(19) United States
(12) Patent Application Publication
(10) Pub. No.: US 2025/0234788 A1
(43) Pub. Date: Jul. 17, 2025

(54) MAGNETIC MEMORY DEVICE AND METHOD OF MANUFACTURING THE SAME

(71) Applicant: Samsung Electronics Co., Ltd., Suwon-si (KR)

(72) Inventors: Jeong-Heon Park, Suwon-si (KR); Cheol Kim, Suwon-si (KR); Hyung-Yong Kim, Suwon-si (KR); Jinho Park, Suwon-si (KR)

(73) Assignee: Samsung Electronics Co., Ltd., Suwon-si (KR)

(21) Appl. No.: 18/781,188

(22) Filed: Jul. 23, 2024

(30) Foreign Application Priority Data
Jan. 17, 2024 (KR) 10-2024-0007346

(51) Int. Cl. H10N 50/01; G11C 11/16; H10B 61/00; H10N 50/10; H10N 50/85

(52) U.S. Cl. CPC H10N 50/01; G11C 11/161; H10B 61/00; H10N 50/10; H10N 50/85

(57) ABSTRACT

A magnetic memory device includes a substrate, an interlayer insulating layer on the substrate, a data storage structure on the interlayer insulating layer, and a plurality of metal oxides on at least one side surface of the data storage structure, where the data storage structure includes a lower electrode, a magnetic tunnel junction pattern, and an upper electrode sequentially stacked on the interlayer insulating layer, and at least one metal oxide of the plurality of metal oxides contacts a side surface of the upper electrode.

### CROSS-REFERENCE TO RELATED APPLICATION

This application is based on and claims priority under 35 U.S.C. § 119 to Korean Patent Application No.10-2024-0007346, filed on Jan. 17, 2024, in the Korean Intellectual Property Office, the disclosure of which is incorporated by reference herein in its entirety.

### BACKGROUND

Example embodiments of the disclosure relate to a magnetic memory device and a method of manufacturing the same, and particularly to a magnetic memory device including a magnetic tunnel junction and a method of manufacturing the same.

High-speed and/or low-voltage semiconductor memory devices have been demanded to realize power consumption electronic devices. Magnetic memory devices have been developed to satisfy these demands. The magnetic memory devices have high-speed operational and/or non-volatile characteristics.

High integrated and/or low power consumption magnetic memory devices have been increasingly demanded with the development of an electronic industry. Thus, various research is being conducted for magnetic memory devices capable of satisfying the demands.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide to a magnetic memory device with improved electrical characteristics and a method of manufacturing the same.

Additional aspects will be set forth in part in the description which follows and, in part, will be apparent from the description, or may be learned by practice of the presented embodiments.

According to an aspect of an example embodiment, a magnetic memory device may include a substrate, an interlayer insulating layer on the substrate, a data storage structure on the interlayer insulating layer, and a plurality of metal oxides on at least one side surface of the data storage structure, where the data storage structure includes a lower electrode, a magnetic tunnel junction pattern, and an upper electrode sequentially stacked on the interlayer insulating layer, and at least one metal oxide of the plurality of metal oxides contacts a side surface of the upper electrode.

According to an aspect of an example embodiment, a magnetic memory device may include a substrate, an interlayer insulating layer on the substrate, a data storage structure on the interlayer insulating layer, and a plurality of metal oxides including a first plurality of metal oxides on an upper surface of the interlayer insulating layer and a second plurality of metal oxides on at least one side surface of the data storage structure, where the data storage structure includes a lower electrode, a magnetic tunnel junction pattern, and an upper electrode sequentially stacked on the interlayer insulating layer, the magnetic tunnel junction pattern includes a first magnetic pattern, a tunnel barrier pattern on the first magnetic pattern, and a second magnetic pattern on the tunnel barrier pattern, the second magnetic pattern is between the tunnel barrier pattern and the upper electrode, and some of the second plurality of metal oxides on the at least one side surface of the data storage structure are above the second magnetic pattern.

According to an aspect of an example embodiment, a method of manifesting a magnetic memory device may include providing a substrate, and forming a data storage structure pattern on the substrate, where the forming of the data storage structure pattern includes forming a data storage structure layer and etching the data storage structure layer, and where the forming of the data storage structure layer includes forming a lower electrode layer, a magnetic tunnel junction layer, and an upper electrode layer sequentially on the substrate, forming a hard mask pattern on the upper electrode layer, and performing an oxygen ion implantation process on portions of the data storage structure layer that are exposed between the hard mask pattern.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a unit memory cell of a magnetic memory device according to one or more embodiments;

FIG. 2 is a plan view illustrating a magnetic memory device according to one or more embodiments;

FIG. 3 is a cross-sectional view taken along line A-A′ in FIG. 2 according to one or more embodiments;

FIG. 4 is an enlarged view of portion ‘CU’ of FIG. 3 according to one or more embodiments;

FIG. 5 is a cross-sectional view illustrating an example of a magnetic tunnel junction pattern of a magnetic memory device according to one or more embodiments;

FIG. 6 is a cross-sectional view illustrating an example of a magnetic tunnel junction pattern of a magnetic memory device according to one or more embodiments;

FIGS. 7A, 8A, 9A, 10A, 11A, and 12A are plan views illustrating manufacturing processes of magnetic memory devices according to one or more embodiments;

FIGS. 7B, 8B, 9B, 10B, 11B, 12B, and 13B are cross-sectional views taken along line B-B′ of FIGS. 7A, 8A, 9A, 10A, 11A, and 12A, respectively, according to one or more embodiments;

FIGS. 13A and 14A are plan views illustrating manufacturing processes of a magnetic memory device according to one or more embodiments; and

FIGS. 13B and 14B are cross-sectional views taken along line C-C′ of FIGS. 13A and 14A, respectively, according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

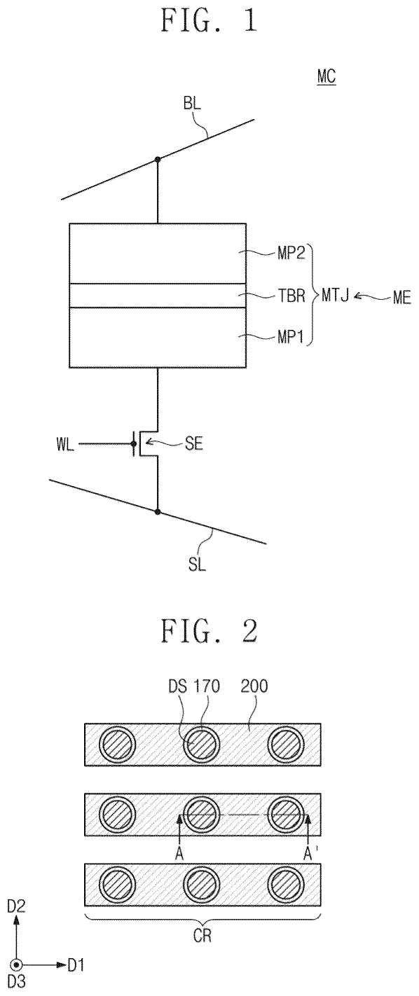

FIG. 1 is a diagram illustrating a unit memory cell of a magnetic memory device according to one or more embodiments.

Referring to FIG. 1, a unit memory cell MC may include a memory element ME and a selection element SE. The memory element ME and the selection element SE may be electrically connected to each other in series. The memory element ME may be provided between and connected to a bit line BL and the selection element SE. The selection element SE may be provided between and connected to the memory element ME and a source line SL, and may be controlled by a word line WL. The selection element SE may include, for example, a bipolar transistor or a metal-oxide-semiconductor (MOS) field effect transistor (FET) (MOSFET).

The memory element ME may include a magnetic tunnel junction MTJ including magnetic patterns MP1 and MP2, which are spaced apart from each other, and a tunnel barrier pattern TBP, which is interposed between the magnetic patterns MP1 and MP2.

Generally, the magnetic memory device may include a magnetic tunnel junction pattern. The magnetic tunnel junction pattern may include two magnetic layers and an insulating layer disposed therebetween. A resistance value of the magnetic tunnel junction pattern may be changed depending on magnetization directions of the two magnetic layers. For example, when the magnetization directions of the two magnetic layers are anti-parallel to each other, the magnetic tunnel junction pattern may have a high resistance value. When the magnetization directions of the two magnetic layers are parallel to each other, the magnetic tunnel junction pattern may have a low resistance value. Logical data may be written/read using a difference between the high and low resistance values of the magnetic tunnel junction pattern.

One of the magnetic patterns MP1 and MP2 may have a fixed magnetization direction, regardless of the presence of an external magnetic field generated under a typical use condition. Thus, one of the magnetic patterns MP1 and MP2 may serve as a reference magnetic pattern of the magnetic tunnel junction MTJ, and the other of the magnetic patterns MP1 and MP2 may have a magnetization direction, which is capable of being changed to one of two stable magnetization directions by an external magnetic field. Therefore, the other of the magnetic patterns MP1 and MP2 may serve as a free magnetic pattern of the magnetic tunnel junction MTJ. The electrical resistance of the magnetic tunnel junction MTJ may be greater when magnetization directions of the reference magnetic pattern and the free magnetic pattern are antiparallel than when they are parallel. In other words, the electrical resistance of the magnetic tunnel junction MTJ may be controlled by adjusting the magnetization direction of the free magnetic pattern. Thus, a difference in electrical resistance of the magnetic tunnel junction pattern MTJ, which is caused by a difference in magnetization direction between the reference and free magnetic patterns, may be used as a data storing mechanism in the memory element ME.

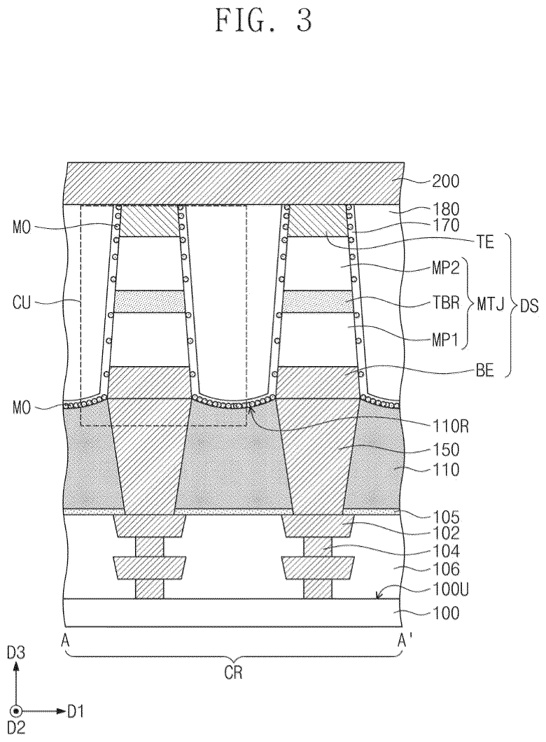

FIG. 2 is a plan view illustrating a magnetic memory device according to one or more embodiments. FIG. 3 is a cross-sectional view taken along line A-A′ in FIG. 2 according to one or more embodiments.

Referring to FIGS. 2 and 3, a substrate 100 including a cell region CR and a peripheral region may be provided. The substrate 100 may be a semiconductor substrate including silicon (Si), silicon on insulator (SOI), silicon germanium (SiGe), germanium (Ge), gallium arsenide (GaAs), and so forth. The cell region CR may be a region of the substrate 100 where the memory cells MC of FIG. 1 are provided, and the peripheral region may be another region of the substrate 100 where peripheral circuits for driving the memory cells MC are provided.

As shown in FIG. 2, a plurality of data storage structures DS may be arranged on the substrate 100 to be spaced apart in a first direction D1 and a second direction D2. A detailed description of the data storage structures DS is provided below.

The first direction D1 may be defined as a direction parallel to an upper surface 100U of the substrate 100. The second direction D2 may be parallel to the upper surface 100U of the substrate 100 and may be defined as a direction perpendicular to the first direction D1. A third direction D3 may be defined as a direction perpendicular to the upper surface 100U of the substrate 100.

Interconnection structures 102 and 104 may be disposed on the substrate 100. The interconnection structures 102 and 104 may include lower interconnections 102 and lower contacts 104 connected to the lower interconnections 102. The lower interconnections 102 may be spaced apart from the upper surface 100U of the substrate 100 in the third direction D3.

The lower contacts 104 may be disposed between the substrate 100 and the lower interconnections 102, and each of the lower interconnections 102 may be electrically connected to the substrate 100 through a corresponding one of the lower contacts 104. The lower interconnections 102 and the lower contacts 104 may include metal (e.g., copper).

The selection elements SE (e.g., see FIG. 1) may be disposed on the substrate 100. The selection elements may be, for example, FETs. Each of the lower interconnections 102 may be electrically connected to a corresponding one terminal (e.g., a drain terminal) of the selection elements SE through a corresponding one of the lower contacts 104.

A first lower interlayer insulating layer 106 may be disposed on the substrate 100 to cover the interconnection structures 102 and 104. The first lower interlayer insulating layer 106 may include, for example, silicon oxide, silicon nitride, and/or silicon oxynitride.

A lower insulating layer 105 may be disposed on the first lower interlayer insulating layer 106. The lower insulating layer 105 may cover exposed upper surfaces of the uppermost lower interconnections 102.

A second lower interlayer insulating layer 110 may be disposed on the lower insulating layer 105. That is, the lower insulating layer 105 may be interposed between the first lower interlayer insulating layer 106 and the second lower interlayer insulating layer 110. In this case, an upper surface of the second lower interlayer insulating layer 110 may have a recessed portion 110R facing the substrate 100. That is, the recessed portion 110R may protrude downward toward the substrate 100.

The lower insulating layer 105 may include a material that has etch selectivity with respect to the first and second lower interlayer insulating layers 106 and 110. The lower insulating layer 105 may include, for example, silicon nitride (SiCN). For example, the second lower interlayer insulating layer 110 may include silicon oxide.

Lower contact plugs 150 may be disposed in the second lower interlayer insulating layer 110. The lower contact plugs 150 may penetrate the second lower interlayer insulating layer 110 and the lower insulating layer 105, and may be electrically connected to the corresponding lower interconnections 102. The lower contact plug 150 may include at least one of a doped semiconductor material (e.g., doped silicon), a metal (e.g., tungsten, titanium, and/or tantalum), a metal-semiconductor compound (e.g., metal silicide), and a conductive metal nitride (e.g., ex, titanium nitride, tantalum nitride, and/or tungsten nitride).

Data storage structures DS may be disposed on the second lower interlayer insulating layer 110 and the lower contact plug 150. The data storage structure DS may also be referred to as a data storage structure pattern DS. Each of the data storage structures DS may be electrically connected to the corresponding lower contact plug 150.

Each of the data storage structures DS may include a lower electrode BE, a magnetic tunnel junction pattern MTJ, and an upper electrode TE that are sequentially stacked on the corresponding lower contact plugs 150. The lower electrode BE may be disposed between each of the lower contact plugs 150 and the magnetic tunnel junction pattern MTJ, and the magnetic tunnel junction pattern MTJ may be disposed between the lower electrode BE and the upper electrode TE.

The magnetic tunnel junction pattern MTJ may include a first magnetic pattern MP1, a second magnetic pattern MP2, and a tunnel barrier pattern TBR therebetween. The first magnetic pattern MP1 may be disposed between the lower electrode BE and the tunnel barrier pattern TBR, and the second magnetic pattern MP2 may be disposed between the upper electrode TE and the tunnel barrier pattern TBR. That is, the tunnel barrier pattern TBR may be disposed on the first magnetic pattern MP1, and the second magnetic pattern MP2 may be disposed on the tunnel barrier pattern TBR.

The lower electrode BE and the upper electrode TE may include a metallic material (e.g., titanium (Ti), tantalum (Ta), platinum (Pt), palladium (Pd), copper (Cu), tungsten (W), molybdenum (Mo), ruthenium (Ru)) and a conductive metal nitride (e.g., titanium nitride or tantalum nitride).

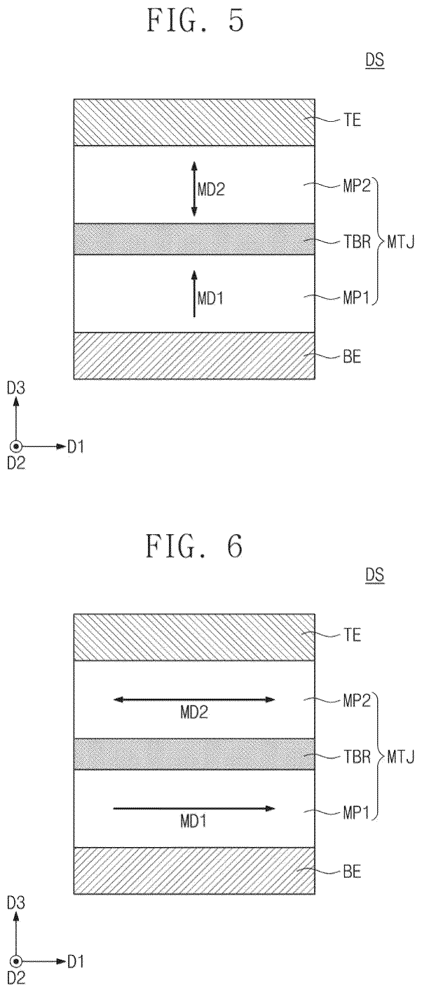

The magnetic tunnel junction pattern MTJ may include a metallic material (e.g., cobalt (Co), iron (Fe), nickel (Ni), tungsten (W), molybdenum (Mo), tantalum (Ta), ruthenium (Ru), platinum (Pt), zirconium (Zr), copper (Cu), iridium (Ir), and rhodium (Rh)), and a detailed description of the magnetic tunnel junction pattern MTJ will be described later in FIGS. 5 and 6.

A capping pattern may be disposed between the magnetic tunnel junction pattern MTJ and the upper electrode TE. The capping pattern may include at least one of tantalum (Ta), ruthenium (Ru), molybdenum (Mo), aluminum (Al), copper (Cu), gold (Au), silver (Ag), titanium (Ti), tantalum nitride (TaN) and titanium nitride (TiN).

A protective insulating layer 170 may be disposed on an upper surface of the second lower interlayer insulating layer 110 to cover the recessed portion 110R. The protective insulating layer 170 may extend on each side surface of the data storage structures DS and surround each side surface of the data storage structures DS in a plan view. That is, the protective insulating layer 170 may cover the side surfaces of the lower electrode BE, the magnetic tunnel junction pattern MTR, and the upper electrode TE. For example, the protective insulating layer 170 may include silicon nitride. Put alternatively, the protective insulating layer 170 may conformally cover top surfaces of the recessed portions 110R of the second lower interlayer insulating layer 110 and side surfaces of the data storage structures DS.

An upper insulating layer 180 may be disposed on the second lower interlayer insulating layer 110. The upper insulating layer 180 may fill a space between the data storage structures DS. That is, the protective insulating layer 170 may be interposed between the upper insulating layer 180 and each side surface of the data storage structures DS.

An upper interconnection layer 200 may be disposed on the data storage structures DS and the upper insulating layer 180. The upper interconnection layer 200 may extend in the first direction D1. The data storage structures DS may be electrically connected to the upper interconnection layer 200. Specifically, the upper electrode TE of the data storage structures DS may be connected to a lower surface of the upper interconnection layer 200, and the uppermost surface of the protective insulating layer 170 may contact the lower surface of the upper interconnection layer 200. The upper interconnection layer 200 may be electrically connected to the magnetic tunnel junction pattern MTJ through the upper electrode TE and may function as the bit line BL (e.g., see FIG. 1).

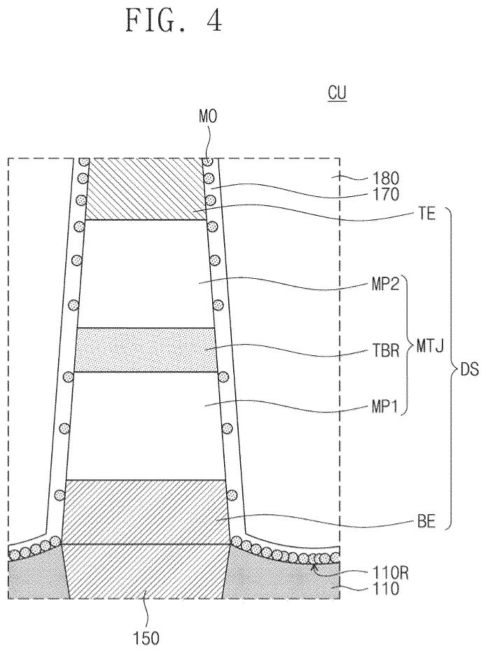

FIG. 4 is an enlarged view of portion ‘CU’ of FIG. 3 according to one or more embodiments.

Referring to FIG. 4, metal oxides MO may be provided on an upper surface of the second lower interlayer insulating layer 110 (e.g., on the upper surfaces of the recessed portions 110R) and side surfaces of the data storage structure DS. According to one or more embodiments, oxygen ions may be provided with the metal oxides MO on the upper surface of the second lower interlayer insulating layer 110 and the side surface of the data storage structure DS. An amount of metal oxides MO per unit area (e.g., a density of metal oxides, a concentration of metal oxides, etc.) on the second lower interlayer insulating layer 110 may be higher than an amount of metal oxides MO per unit area (e.g., a density of metal oxides, a concentration of metal oxides, etc.) on the side surface of the data storage structure DS.

Specifically, the metal oxides MO may contact the recessed portion 110R of the second lower interlayer insulating layer 110 and the side surfaces of the lower electrode BE, the first magnetic pattern MP1, the tunnel barrier pattern TBR, and the upper electrode TE. That is, some of the metal oxides MO on the side surface of the data storage structure DS may be disposed above the second magnetic pattern MP2. The protective insulating layer 170 may cover the metal oxides MO on the upper surface of the second lower interlayer insulating layer 110 and the side surfaces of the data storage structure DS.

The metal oxides MO on the side surface of the data storage structure DS may have a concentration gradient in the third direction D3. That is, an amount of metal oxides MO per unit area (e.g., a density of metal oxides, a concentration of metal oxides, etc.) of metal oxides MO on the side surface of the data storage structure DS may increase from the side surface of the lower electrode BE to the side surface of the upper electrode TE.

Each of the lower electrode BE, the magnetic tunnel junction pattern MTJ, and the upper electrode TE may include metallic materials, and the metal oxides MO may be oxides of at least some of the metallic materials. Specifically, in an ion beam etching process (FIGS. 11A and 11B), when oxidized portions of a lower electrode layer (BEL of FIGS. 11A and 11B), a magnetic tunnel junction layer (MTJL of FIGS. 11A and 11B), and an upper electrode layer (190L of FIGS. 11A and 11B) are etched, the metal oxides MO may be a redeposited material attached to side surfaces of the data storage structure DS and the upper surface of the second lower interlayer insulating layer 110. As an example, the metal oxides MO may be an oxide of titanium (Ti), tantalum (Ta), platinum (Pt), palladium (Pd), copper (Cu), tungsten (W), molybdenum (Mo), and ruthenium (Ru)., cobalt (Co), iron (Fe), nickel (Ni), zirconium (Zr), copper (Cu), iridium (Ir), and rhodium (Rh).

FIG. 5 is a cross-sectional view illustrating an example of a magnetic tunnel junction pattern of a magnetic memory device according to one or more embodiments. FIG. 6 is a cross-sectional view illustrating an example of a magnetic tunnel junction pattern of a magnetic memory device according to one or more embodiments.

Referring to FIGS. 5 and 6, the first magnetic pattern MP1 may be a reference layer, having a magnetization direction MD1 fixed to a specific direction, and the second magnetic pattern MP2 may be a free layer, having a magnetization direction MD2 that may be changed to be parallel or antiparallel to the magnetization direction MD1 of the first magnetic pattern MP1. FIGS. 5 and 6 illustrate an example, in which the second magnetic pattern MP2 is used as the free layer, but embodiments are not limited thereto. In one or more embodiments, the first magnetic pattern MP1 may be the free layer and the second magnetic pattern MP2 may be the reference layer.

Referring to FIG. 5, as an example, the magnetization directions MD1 and MD2 of the first and second magnetic patterns MP1 and MP2 may be substantially perpendicular to an interface of the tunnel barrier pattern TBR and second magnetic pattern MP2. In this case, each of the first and second magnetic patterns MP1 and MP2 may include an intrinsic perpendicular magnetic material or an extrinsic perpendicular magnetic material. The intrinsic perpendicular magnetic material may include a material which has a perpendicular magnetization property even though an external factor does not exist. The intrinsic perpendicular magnetic material may include, for example, a perpendicular magnetic material (e.g., CoFeTb, CoFeGd, or CoFeDy), a perpendicular magnetic material having a L1₀ structure, a CoPt alloy having a hexagonal close packed (HCP) lattice structure, or a perpendicular magnetic structure. The perpendicular magnetic material having the L1₀ structure may include, for example, FePt having the L1₀ structure, FePd having the L1₀ structure, CoPd having the L1₀ structure, or CoPt having the L1₀ structure. The perpendicular magnetic structure may include magnetic layers and non-magnetic layers, which are alternately and repeatedly stacked. As an example, the perpendicular magnetic structure may include at least one of (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n, where ‘n’ denotes the number of bilayers. The extrinsic perpendicular magnetic material may include a material which has an intrinsic horizontal magnetization property but has a perpendicular magnetization property by an external factor. For example, the extrinsic perpendicular magnetic material may have the perpendicular magnetization property by magnetic anisotropy induced by a junction of the tunnel barrier pattern TBR and the first magnetic pattern MP1 (or the second magnetic pattern MP2). The extrinsic perpendicular magnetic material may include, for example, CoFeB.

Referring to FIG. 6, as another example, the magnetization directions MD1 and MD2 of the first magnetic pattern MP1 and the second magnetic pattern MP2 may be parallel to an interface between the tunnel barrier pattern TBR and the second magnetic pattern MP2. In this case, each of the first magnetic pattern MP1 and the second magnetic pattern MP2 may include a ferromagnetic material. The first magnetic pattern MP1 may further include an antiferromagnetic material for fixing the magnetization direction of the ferromagnetic material in the first magnetic pattern MP1.

Each of the first magnetic pattern MP1 and the second magnetic pattern MP2 may include a Co-based Heusler alloy. The tunnel barrier pattern TBR may include at least a magnesium oxide (MgO) layer, a titanium oxide (TiO) layer, an aluminum oxide (AlO) layer, a magnesium-zinc oxide (MgZnO) layer, or a magnesium-boron oxide (MgBO) layer.

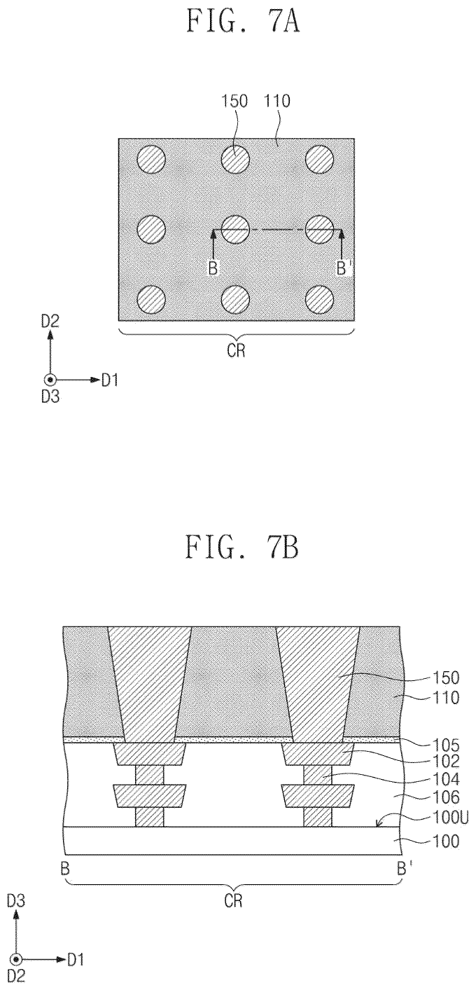

FIGS. 7A, 8A, 9A, 10A, 11A, and 12A are plan views illustrating manufacturing processes of magnetic memory devices according to one or more embodiments. FIGS. 7B, 8B, 9B, 10B, 11B, 12B, and 13B are cross-sectional views taken along line B-B′ of FIGS. 7A, 8A, 9A, 10A, 11A, and 12A, respectively, according to one or more embodiments.

Referring to FIGS. 7A and 7B, a substrate 100 may be provided, and selection elements may be formed on the substrate 100. A first lower interlayer insulating layer 106 may be formed on an upper surface 100U of the substrate 100 to cover the selection elements.

Interconnection structures 102 and 104 may be formed to penetrate the first lower interlayer insulating layer 106, and a lower insulating layer 105 may be formed to cover upper surfaces of the interconnection structures 102 and 104 and the first lower interlayer insulating layer 106.

A second lower interlayer insulating layer 110 may be formed on the lower insulating layer 105. Thereafter, lower contact plugs 150 that penetrate the second lower interlayer insulating layer 110 may be formed. Forming the lower contact plugs 150 may include etching the second lower interlayer insulating layer 110 and the lower insulating layer 105 until an upper surface of the uppermost lower interconnection 102 is exposed to form a hole, and filling the hole with a metallic material.

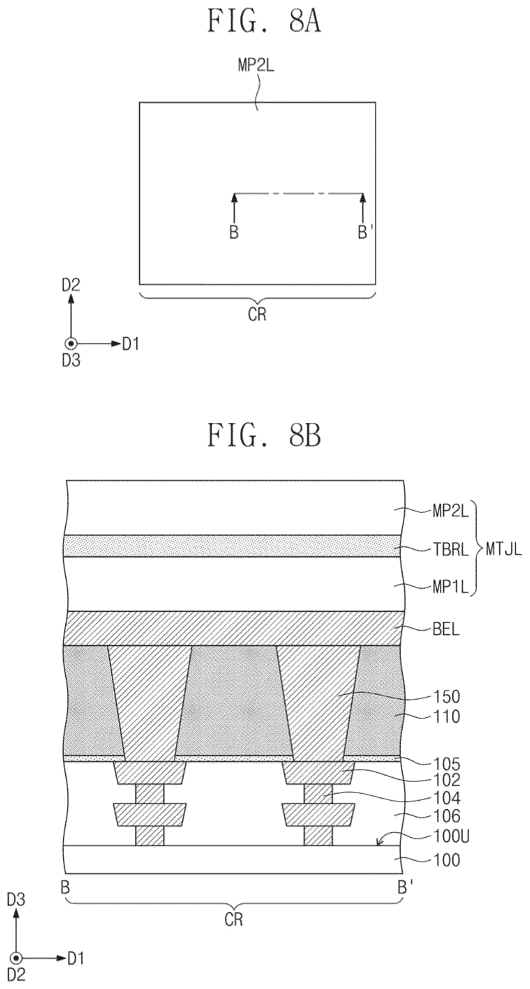

Referring to FIGS. 8A and 8B, a lower electrode layer BEL and a magnetic tunnel junction layer MTJL may be sequentially formed on the second lower interlayer insulating layer 110. The magnetic tunnel junction layer MTJL may include a first magnetic layer MP1L, a tunnel barrier layer TBRL, and a second magnetic layer MP2L sequentially stacked on the lower electrode layer BEL. The lower electrode layer BEL and magnetic tunnel junction layer MTJL may be formed through sputtering, chemical vapor deposition (CVD), physical vapor deposition (PVD), or atomic layer deposition (ALD). After the magnetic tunnel junction layer MTJL is formed, a capping layer may be formed on the second magnetic layer MP2L.

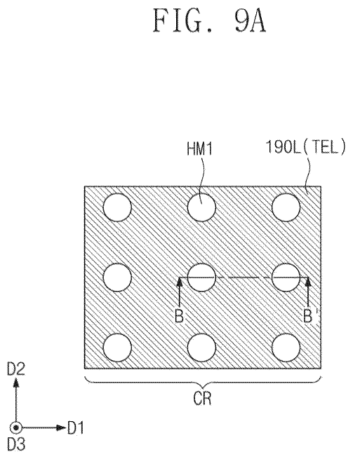

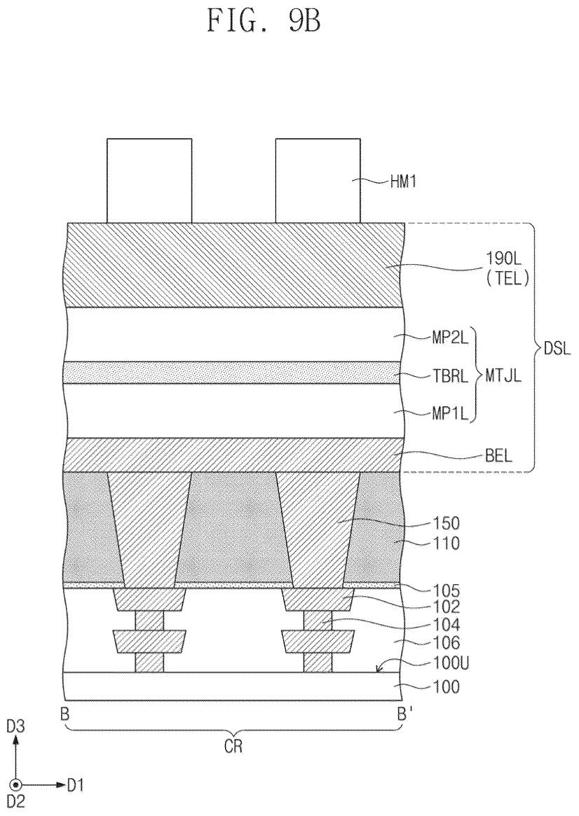

Referring to FIGS. 9A and 9B, an upper electrode layer 190L may be formed on the magnetic tunnel junction layer MTJL. The upper electrode layer 190L may also be referred to as an upper electrode layer TEL. As the upper electrode layer 190L is formed, a data storage structure layer DSL including the lower electrode layer BEL, the magnetic tunnel junction layer MTJL, and the upper electrode layer 190L may be formed.

Thereafter, a first hard mask pattern HM1 may be formed on the upper electrode layer 190L. The first hard mask pattern HM1 may define a portion where the data storage structure DS described in FIGS. 2 and 3 will be formed. That is, the region of the data storage structure layer DSL that overlaps the first hard mask pattern HM1 may be a region where the data storage structure DS described in FIGS. 2 and 3 will be formed.

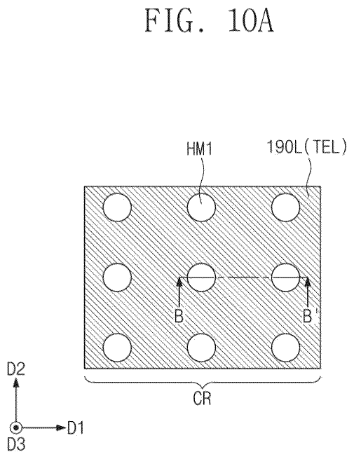

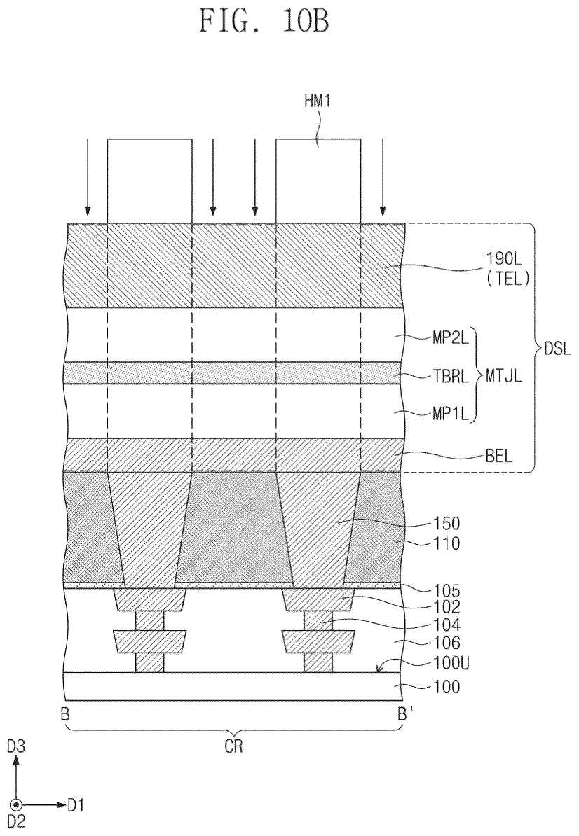

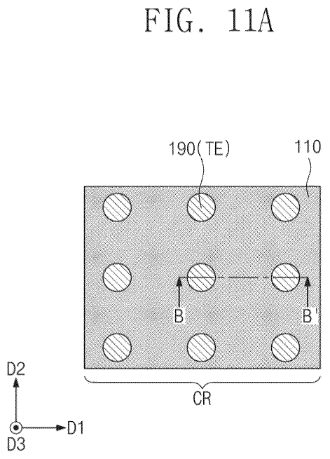

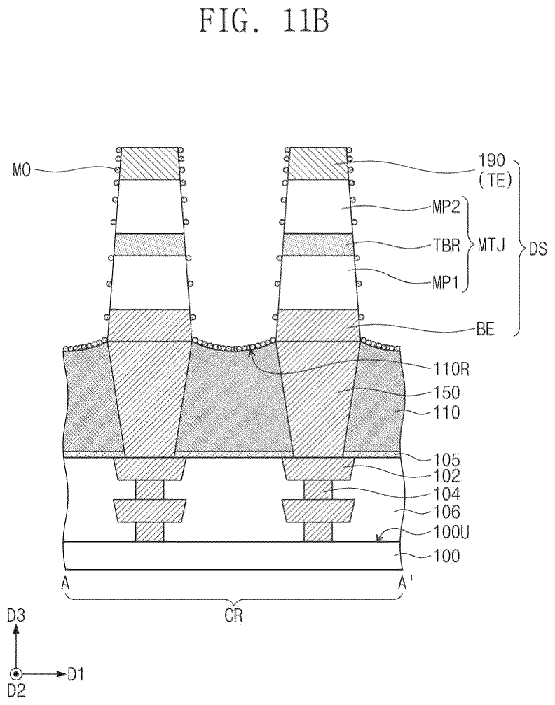

Referring to FIGS. 10A and 10B, an oxygen ion implantation process may be performed on a portion of the data storage structure layer DSL where the first hard mask pattern HM1 is not disposed. A concentration of oxygen ions injected into the data storage structure layer DSL through the oxygen ion implantation process may increase from the lower electrode layer BEL to the upper electrode layer 190L. The ion implantation process may be performed in a range of 10 nm to 999 nm in the third direction D3 on an upper surface of the data storage structure layer DSL. In this case, the ion implantation energy used in the oxygen ion implantation process may be 10 keV to 80 keV.

As the oxygen ion implantation process is performed, some regions of the data storage structure layer DSL where the first hard mask pattern HM1 is not disposed may include metal oxide. According to one or more embodiments, the oxygen ion implantation process may be performed in a vacuum state.

After the first hard mask pattern HM1 is removed, a heat treatment process may be performed on the data storage structure layer DSL. The heat treatment process may be performed at a temperature of 200° C. to 400° C. for 1 hour to 2 hours.

Referring to FIGS. 11A and 11B, the upper electrode layer 190L may be patterned to form a conductive mask pattern 190. The conductive mask pattern 190 may define a region where the data storage structure DS of FIGS. 2 and 3 will be formed.

Thereafter, the magnetic tunnel junction layer MTJL and the lower electrode layer BEL may be sequentially etched using the conductive mask pattern 190 as an etch mask. As the magnetic tunnel junction layer MTJL and the lower electrode layer BEL are etched, a magnetic tunnel junction pattern MTJ and a lower electrode BE may be formed on the second lower interlayer insulating layer 110.

Etching the magnetic tunnel junction layer MTJL may include sequentially etching the second magnetic layer ML2, the tunnel barrier layer TBL, and the first magnetic layer ML1 using the conductive mask patterns 190 as an etch mask. The second magnetic layer ML2, the tunnel barrier layer TBL, and the first magnetic layer ML1 may be etched to form a second magnetic pattern MP2, a tunnel barrier pattern TBR, and a first magnetic pattern MP1, respectively.

For example, the etching process for etching the magnetic tunnel junction layer MTJL and the lower electrode layer BEL may be an ion beam etching process using an ion beam. The ion beam may contain inert ions. A recessed portion 110R may be formed on an upper surface of the second lower interlayer insulating layer 110 through the etching process.

After the etching process, at least a portion of the conductive mask pattern 190 may remain on the magnetic tunnel junction pattern MTJ. The conductive mask pattern 190 may function as an upper electrode TE. That is, the conductive mask pattern 190 may be referred to as upper electrodes TE. The upper electrode TE, magnetic tunnel junction pattern MTJ, and lower electrode BE may constitute a data storage structure DS.

When the data storage structure layer DSL is etched to form the data storage structures DS, metal oxides MO may be redeposited on side surfaces of the data storage structures DS, as well as on the upper surfaces of the recessed portion 110R of the second lower interlayer insulating layer 110. The metal oxides MO may contact side surfaces of the upper electrodes 190/TE. Thus, metal oxides MO with reduced conductivity may be attached to side surfaces of the data storage structures DS, as well as the upper surfaces of the recessed portions 110R, thereby reducing the electrical short phenomenon of the data storage structures DS.

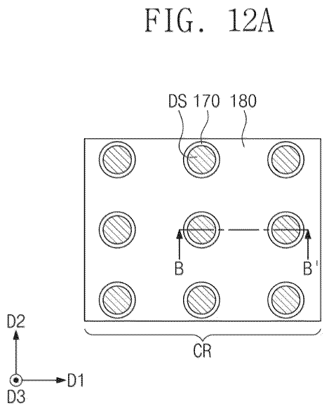

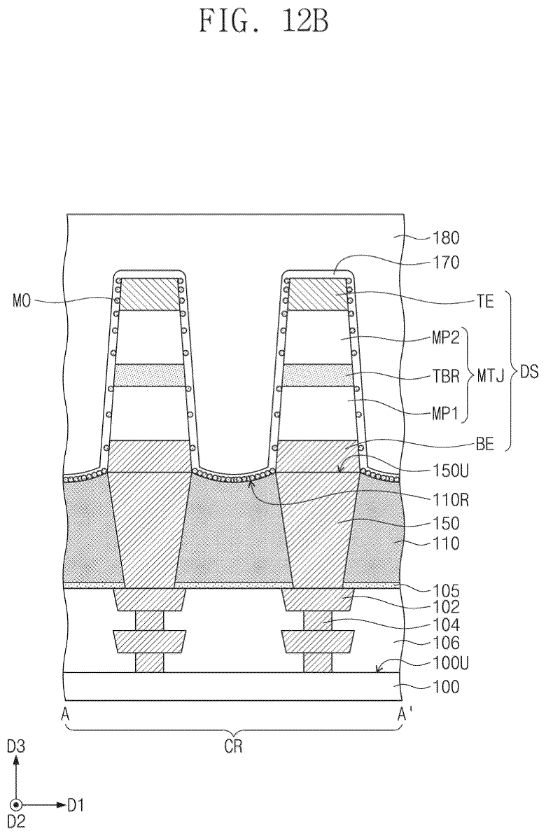

Referring to FIGS. 12A and 12B, a protective insulating layer 170 may be formed on the second lower interlayer insulating layer 110. The protective insulating layer 170 may conformally cover the upper and side surfaces of the data storage structures DS and cover the recessed portion 110R of the second lower interlayer insulating layer 110.

An upper insulating layer 180 may be formed on the protective insulating layer 170. The upper insulating layer 180 may cover the data storage structures DS and fill a space between the data storage structures DS.

After removing the upper portion of the protective insulating layer 170 and the upper insulating layer 180, an upper interconnection layer 200 may be formed on the upper insulating layer 180 and the data storage structure DS, thereby forming the magnetic memory device as shown in FIG. 3.

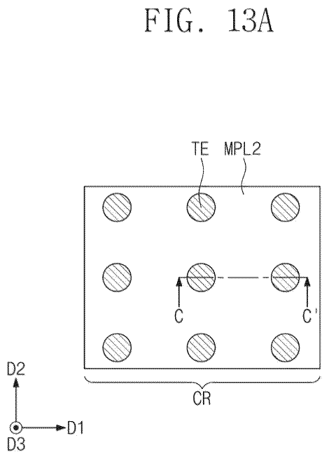

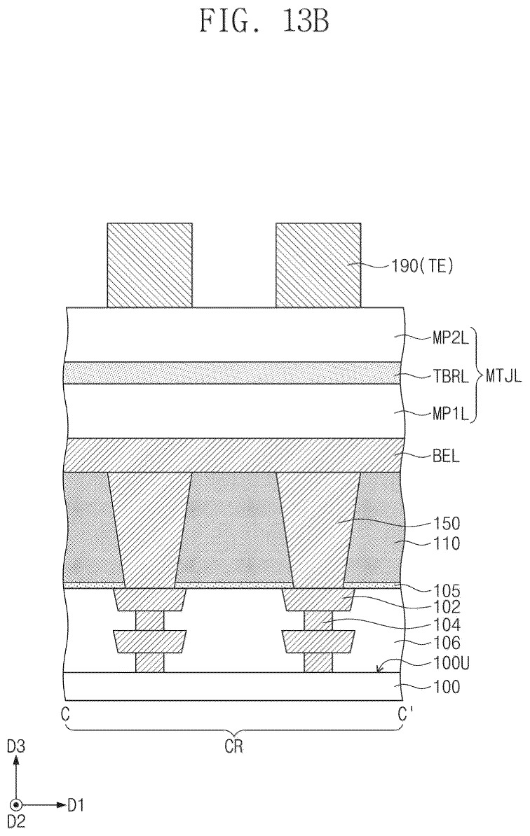

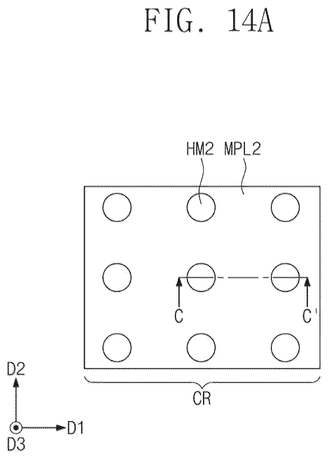

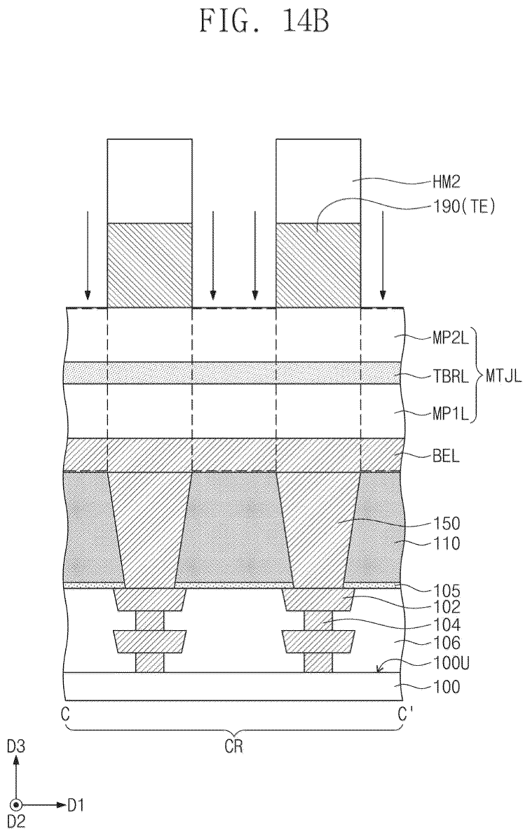

FIGS. 13A and 14A are plan views illustrating manufacturing processes of a magnetic memory device according to one or more embodiments. FIGS. 13B and 14B are cross-sectional views taken along line C-C′ of FIGS. 13A and 14A, respectively, according to one or more embodiments.

Referring to FIGS. 8A, 8B, 13A, and 13B, a conductive mask pattern 190 may be formed on the magnetic tunnel junction layer MTJL. The conductive mask pattern 190 may define a region where the data storage structure DS of FIG. 3 will be formed. Forming the conductive mask pattern 190 may include forming an upper electrode layer on the magnetic tunnel junction layer MTJL and patterning the upper electrode layer.

Referring to FIGS. 14A and 14B, a second hard mask pattern HM2 may be formed on the conductive mask pattern 190. Thereafter, an oxygen ion implantation process may be performed on some regions of the magnetic tunnel junction layer MTJL and the lower electrode layer BEL where the second hard mask pattern HM2 and the conductive mask pattern 190 are not disposed. A concentration of oxygen ions injected into the magnetic tunnel junction layer MTJL and the lower electrode layer BEL through the oxygen ion implantation process may increase from the lower electrode layer BEL to the second magnetic layer MP2L included in the magnetic tunnel junction layer MTJL.

As the oxygen ion implantation process is performed, an inner region of the lower electrode layer BEL and the magnetic tunnel junction layer MTJL where the second hard mask pattern HM2 and the conductive mask pattern 190 are not disposed may include metal oxide.

After the oxygen ion implantation process, the second hard mask pattern HM2 may be removed. After the second hard mask pattern HM2 is removed, a process similar to the process described in FIGS. 11A to 12A may be performed on the magnetic tunnel junction layer MTJL using the conductive mask pattern 190 as an etch mask, thereby forming the magnetic memory device shown in FIG. 3.

In the manufacturing process of the magnetic memory device according to one or more embodiments, the oxygen ion implantation process may be performed on the data storage structure layer before etching the data storage structure layer. As the oxygen ion implantation process is performed, some regions of the data storage structure layer may include metal oxide. When the data storage structure layer is etched to form the data storage structure patterns, the metal oxides may be redeposited on the side surfaces of each of the data storage structure patterns and on the interlayer insulating layer between the data storage structure patterns. Therefore, the metal oxides with reduced conductivity may be attached to the side surfaces of the data storage structure pattern, thereby reducing electrical short circuit phenomenon of the data storage structure pattern. Additionally, electrical leakage between data storage structure patterns may be reduced due to the metal oxides on the interlayer insulating layer. As a result, electrical performance and reliability of the magnetic memory device may be improved.

The magnetic memory device according to one or more embodiments may be provided with the metal oxides on each side surface of the data storage structures. The metal oxides may be the oxides of the metallic materials included in each of the data storage structures, and may have the low conductivity. Due to the metal oxides, the electrical short circuit of the data storage structure may be reduced. As a result, the electrical characteristics and the reliability of the magnetic memory device may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A magnetic memory device comprising:
a substrate;
an interlayer insulating layer on the substrate;
a data storage structure on the interlayer insulating layer; and
a plurality of metal oxides on at least one side surface of the data storage structure,
wherein the data storage structure comprises a lower electrode, a magnetic tunnel junction pattern, and an upper electrode sequentially stacked on the interlayer insulating layer, and
wherein at least one metal oxide of the plurality of metal oxides contacts a side surface of the upper electrode.

2. The magnetic memory device of claim 1, wherein each of the lower electrode, the magnetic tunnel junction pattern, and the upper electrode comprises metallic materials, and
wherein the plurality of metal oxides are oxides of at least one of the metallic materials.

3. The magnetic memory device of claim 2, wherein the plurality of metal oxides comprise oxides of at least one of titanium (Ti), tantalum (Ta), platinum (Pt), palladium (Pd), copper (Cu), tungsten (W), molybdenum (Mo), ruthenium (Ru), cobalt (Co), iron (Fe), nickel (Ni), zirconium (Zr), copper (Cu), iridium (Ir), and rhodium (Rh).

4. The magnetic memory device of claim 1, further comprising a protective insulating layer on a side surface of the interlayer insulating layer,
wherein the protective insulating layer covers at least one metal oxide of the plurality of metal oxides.

5. The magnetic memory device of claim 4, wherein the interlayer insulating layer comprises silicon oxide, and
wherein the protective insulating layer comprises silicon nitride.

6. A magnetic memory device comprising:
a substrate;
an interlayer insulating layer on the substrate;
a data storage structure on the interlayer insulating layer; and
a plurality of metal oxides comprising a first plurality of metal oxides on an upper surface of the interlayer insulating layer and a second plurality of metal oxides on at least one side surface of the data storage structure,
wherein the data storage structure comprises a lower electrode, a magnetic tunnel junction pattern, and an upper electrode sequentially stacked on the interlayer insulating layer,
wherein the magnetic tunnel junction pattern comprises a first magnetic pattern, a tunnel barrier pattern on the first magnetic pattern, and a second magnetic pattern on the tunnel barrier pattern,
wherein the second magnetic pattern is between the tunnel barrier pattern and the upper electrode, and
wherein some of the second plurality of metal oxides on the at least one side surface of the data storage structure are above the second magnetic pattern.

7. The magnetic memory device of claim 6, wherein a first amount of metal oxides per unit area on the upper surface of the interlayer insulating layer is higher than a second amount of metal oxides per unit area on the at least one side surface of the data storage structure.

8. The magnetic memory device of claim 6, wherein each of the lower electrode, the magnetic tunnel junction pattern, and the upper electrode comprises metallic materials, and
wherein the plurality of metal oxides are oxides of at least one of the metallic materials.

9. The magnetic memory device of claim 6, wherein an amount of metal oxides per unit area on the at least one side surface of the data storage structure increases from a side surface of the lower electrode to a side surface of the upper electrode in a first direction perpendicular to a second direction parallel to an upper surface of the substrate.

10. The magnetic memory device of claim 6, further comprising;
a lower interconnection between the substrate and the interlayer insulating layer;
a contact plug between the lower interconnection and the data storage structure, and
an upper interconnection layer on the data storage structure.

11. A method of manufacturing a magnetic memory device, the method comprising:
providing a substrate; and
forming a data storage structure pattern on the substrate,
wherein the forming of the data storage structure pattern comprises:
forming a data storage structure layer; and
etching the data storage structure layer, and
wherein the forming of the data storage structure layer comprises:
forming a lower electrode layer, a magnetic tunnel junction layer, and an upper electrode layer sequentially on the substrate;
forming a hard mask pattern on the upper electrode layer; and
performing an oxygen ion implantation process on portions of the data storage structure layer that are exposed between the hard mask pattern.

12. The method of claim 11, wherein, in the oxygen ion implantation process, an ion implantation energy implanted into the data storage structure layer is 10 keV to 80 keV.

13. The method of claim 11, further comprising performing a heat treatment process on the data storage structure layer after the performing of the oxygen ion implantation process,
wherein the heat treatment process is performed at 200° C. to 400° C.

14. The method of claim 11, wherein the etching of the data storage structure layer comprises performing an ion beam etching process.

15. The method of claim 11, wherein the etching of the data storage structure layer comprises:
forming a conductive mask pattern by patterning the upper electrode layer; and
etching the magnetic tunnel junction layer and the lower electrode layer using the conductive mask pattern as an etch mask.

16. The method of claim 11, wherein the performing of the oxygen ion implantation process comprises forming metal oxides on portions of the data storage structure layer that are not exposed by the hard mask pattern.

17. The method of claim 11, wherein the performing of the oxygen ion implantation process comprises implanting oxygen ions in a range of 10 nm to 999 nm from an upper surface of the data storage structure layer in a first direction perpendicular to a second direction parallel to an upper surface of the substrate.

18. The method of claim 11, further comprising, prior to the forming of the data storage structure pattern:
forming an interlayer insulating layer on the substrate; and
forming a contact plug penetrating the interlayer insulating layer.

19. The method of claim 18, wherein the etching of the data storage structure layer comprises forming a recessed portion at an upper surface of the interlayer insulating layer, the recessed portion facing the substrate.

20. The method of claim 19, further comprising forming a protective insulating layer on a side surface of the data storage structure pattern and the upper surface of the interlayer insulating layer.
